(19) United States
(12) Patent Application Publication
(10) Pub. No.: US 2021/0057215 A1
(43) Pub. Date: Feb. 25, 2021

(54) TREATMENTS TO ENHANCE MATERIAL STRUCTURES

(71) Applicant: Applied Materials, Inc., Santa Clara, CA (US)

(72) Inventor: Steven C. H. HUNG, Sunnyvale, CA (US)

(21) Appl. No.: 17/092,039

(22) Filed: Nov. 6, 2020

Related U.S. Application Data
(63) Continuation-in-part of application No. 16/403,312, filed on May 3, 2019, now Pat. No. 10,872,763.

(51) Int. Cl. H01L 21/02; C23C 16/40; C23C 16/455; C23C 16/02; C23C 16/56; C23C 8/24; C23C 8/36; C23C 8/80

(52) U.S. Cl. CPC H01L 21/02332; H01L 21/0228; H01L 21/02181; H01L 21/0234; H01L 21/02326; H01L 21/02362; C23C 16/405; C23C 16/45525; C23C 16/0227; C23C 16/0272; C23C 16/56; C23C 8/24; C23C 8/36; C23C 8/80; H01L 21/0206; H01L 21/02238; H01L 21/02255; H01L 21/02356; H01L 21/02304

(57) ABSTRACT

A method of forming a semiconductor structure includes pre-cleaning a surface of a substrate, forming an interfacial layer on the pre-cleaned surface of the substrate, depositing a high-κ dielectric layer on the interfacial layer, performing a plasma nitridation process to insert nitrogen atoms in the deposited high-κ dielectric layer, and performing a post-nitridation anneal process to passivate chemical bonds in the plasma nitridated high-κ dielectric layer.

### CROSS-REFERENCE TO RELATED APPLICATIONS

This application is a continuation-in-part application of co-pending U.S. patent application Ser. No. 16/403,312, filed on May 3, 2019, which is incorporated herein by reference.

### BACKGROUND

### Field

Embodiments described herein generally relate to semiconductor device fabrication, and more particularly, to systems and methods of forming a high quality high-κ dielectric material layer in a semiconductor structure.

### Description of the Related Art

As metal-oxide-semiconductor field-effect transistors (MOSFETs) have decreased in size to achieve high device performance and low power consumption, the thickness of a traditional silicon dioxide (5iO₂) gate dielectric has decreased to its physical limit. As a result, replacing the silicon dioxide gate dielectric with a high-κ dielectric material has been inevitable to achieve further scaling. Among various high-κ dielectric materials, hafnium oxide (HfO₂) has been applied since the 45 nm MOSFET technology node due to its high dielectric constant and superior thermal stability on a silicon substrate. However, for further scaling of equivalent oxide thickness (EOT) for the 32 nm MOSFET technology node and beyond, simply decreasing the thickness of a high-κ dielectric material layer is problematic due to an increase of leakage current through the high-κ dielectric material layer.

Thus, there is a need for systems and methods that can be used to form thin (e.g., EOT less than 1 nm) high-κ dielectric material layers having chemical structures that can be controlled to ensure desired structural and electrical properties.

### SUMMARY

Embodiments of the present disclosure provide a method of forming a semiconductor structure. The method includes pre-cleaning a surface of a substrate, forming an interfacial layer on the pre-cleaned surface of the substrate, depositing a high-κ dielectric layer on the interfacial layer, performing a plasma nitridation process to insert nitrogen atoms in the deposited high-κ dielectric layer, and performing a post-nitridation anneal process to passivate chemical bonds in the plasma nitridated high-κ dielectric layer.

Embodiments of the present disclosure also provide a method of forming a semiconductor structure. The method includes pre-cleaning a surface of a substrate, depositing a high-κ dielectric layer on the substrate, and performing a plasma nitridation process to insert nitrogen atoms in the deposited high-κ dielectric layer.

Embodiments of the present disclosure further provide a processing system. A processing system includes a first processing chamber, a second processing chamber, a third processing chamber, a fourth processing chamber, a fifth processing chamber, and a system controller. The system controller is configured to pre-clean a surface of a substrate in the first processing chamber, form an interfacial layer on the pre-cleaned surface of the substrate in the second processing chamber, deposit a high-κ dielectric layer on the interfacial layer in the third processing chamber, expose the deposited high-κ dielectric layer to nitrogen plasma in the fourth processing chamber, and anneal the plasma nitridated high-κ dielectric layer in the fifth processing chamber. The substrate is transferred among the first, second, third, fourth, and fifth processing chambers without breaking vacuum environment in the processing system.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic top-view diagram of an example multi-chamber processing system according to one embodiment.

FIG. 2 is a process flow diagram of a method of forming a semiconductor structure according to one embodiment.

FIGS. 3A and 3B are schematic views of a semiconductor structure according to one embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

As gate structures scale to smaller dimensions, new material structures are being sought to provide improvements. The use of high-κ dielectric materials increases the dielectric constant of the gate structure over conventional gate structures that utilize materials such as silicon oxide. However, similar to silicon oxide, as the thickness of a gate structure is reduced, leakage currents increase. For example, gate leakage increases as the effective oxide thickness decreases. Hence, the inverse relationship between gate leakage and effective oxide thickness may form a limit on the performance of the transistor and the device produced.

High-κ dielectric materials may provide greater channel mobility over silicon oxide at similar thicknesses. As the industry continues to seek lower effective oxide thicknesses without increased gate leakage, efforts to maximize a dielectric constant (also referred to as “κ-value”) of known high-κ materials are reaching limits due to morphological characteristics. Conventional technologies have struggled to overcome natural characteristics of high-κ materials, which may set an upper limit in the κ-value, and subsequent device remodeling in attempts to incorporate new films.

The embodiments described herein provide systems and methods for improving the characteristics of high-κ dielectric materials. By producing high-κ dielectric materials exhibiting a specific morphology or a grain structure, higher dielectric constants and subsequent improved device performance may be enabled. In order to control grain formation in exemplary devices, treatments may be performed to provide activated substrate surfaces that can induce a specific grain growth, as well as to stabilize films after formation, which may result in a higher dielectric constant.

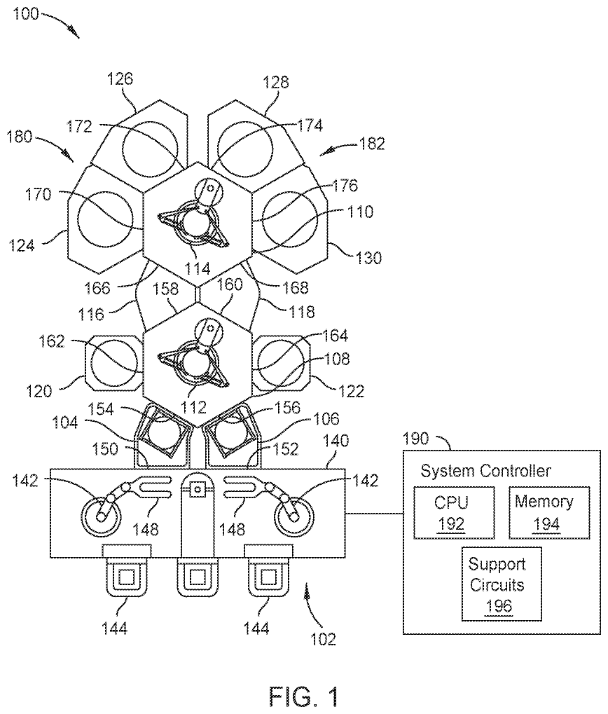

FIG. 1 is a schematic top-view diagram of an example of a multi-chamber processing system 100 according to some examples of the present disclosure. The processing system 100 generally includes a factory interface 102, load lock chambers 104, 106, transfer chambers 108, 110 with respective transfer robots 112, 114, holding chambers 116, 118, and processing chambers 120, 122, 124, 126, 128, 130. As detailed herein, wafers in the processing system 100 can be processed in and transferred between the various chambers without exposing the wafers to an ambient environment exterior to the processing system 100 (e.g., an atmospheric ambient environment such as may be present in a fab). For example, the wafers can be processed in and transferred between the various chambers in a low pressure (e.g., less than or equal to about 300 Torr) or vacuum environment without breaking the low pressure or vacuum environment between various processes performed on the wafers in the processing system 100. Accordingly, the processing system 100 may provide for an integrated solution for some processing of wafers.

Examples of a processing system that may be suitably modified in accordance with the teachings provided herein include the Endura®, Producer® or Centura® integrated processing systems or other suitable processing systems commercially available from Applied Materials, Inc., located in Santa Clara, Calif. It is contemplated that other processing systems (including those from other manufacturers) may be adapted to benefit from aspects described herein.

In the illustrated example of FIG. 1, the factory interface 102 includes a docking station 140 and factory interface robots 142 to facilitate transfer of wafers. The docking station 140 is configured to accept one or more front opening unified pods (FOUPs) 144. In some examples, each factory interface robot 142 generally comprises a blade 148 disposed on one end of the respective factory interface robot 142 configured to transfer the wafers from the factory interface 102 to the load lock chambers 104, 106.

The load lock chambers 104, 106 have respective ports 150, 152 coupled to the factory interface 102 and respective ports 154, 156 coupled to the transfer chamber 108. The transfer chamber 108 further has respective ports 158, 160 coupled to the holding chambers 116, 118 and respective ports 162, 164 coupled to processing chambers 120, 122. Similarly, the transfer chamber 110 has respective ports 166, 168 coupled to the holding chambers 116, 118 and respective ports 170, 172, 174, 176 coupled to processing chambers 124, 126, 128, 130. The ports 154, 156, 158, 160, 162, 164, 166, 168, 170, 172, 174, 176 can be, for example, slit valve openings with slit valves for passing wafers therethrough by the transfer robots 112, 114 and for providing a seal between respective chambers to prevent a gas from passing between the respective chambers. Generally, any port is open for transferring a wafer therethrough. Otherwise, the port is closed.

The load lock chambers 104, 106, transfer chambers 108, 110, holding chambers 116, 118, and processing chambers 120, 122, 124, 126, 128, 130 may be fluidly coupled to a gas and pressure control system (not specifically illustrated). The gas and pressure control system can include one or more gas pumps (e.g., turbo pumps, cryo-pumps, roughing pumps), gas sources, various valves, and conduits fluidly coupled to the various chambers. In operation, a factory interface robot 142 transfers a wafer from a FOUP 144 through a port 150 or 152 to a load lock chamber 104 or 106. The gas and pressure control system then pumps down the load lock chamber 104 or 106. The gas and pressure control system further maintains the transfer chambers 108, 110 and holding chambers 116, 118 with an interior low pressure or vacuum environment (which may include an inert gas). Hence, the pumping down of the load lock chamber 104 or 106 facilitates passing the wafer between, for example, the atmospheric environment of the factory interface 102 and the low pressure or vacuum environment of the transfer chamber 108.

With the wafer in the load lock chamber 104 or 106 that has been pumped down, the transfer robot 112 transfers the wafer from the load lock chamber 104 or 106 into the transfer chamber 108 through the port 154 or 156. The transfer robot 112 is then capable of transferring the wafer to and/or between any of the processing chambers 120, 122 through the respective ports 162, 164 for processing and the holding chambers 116, 118 through the respective ports 158, 160 for holding to await further transfer. Similarly, the transfer robot 114 is capable of accessing the wafer in the holding chamber 116 or 118 through the port 166 or 168 and is capable of transferring the wafer to and/or between any of the processing chambers 124, 126, 128, 130 through the respective ports 170, 172, 174, 176 for processing and the holding chambers 116, 118 through the respective ports 166, 168 for holding to await further transfer. The transfer and holding of the wafer within and among the various chambers can be in the low pressure or vacuum environment provided by the gas and pressure control system.

The processing chambers 120, 122, 124, 126, 128, 130 can be any appropriate chamber for processing a wafer. In some examples, the processing chamber 122 can be capable of performing a cleaning process, the processing chamber 120 can be capable of performing an etch process, and the processing chambers 124, 126, 128, 130 can be capable of performing respective epitaxial growth processes. The processing chamber 122 may be a SiCoNi™ Preclean chamber available from Applied Materials of Santa Clara, Calif. The processing chamber 120 may be a Selectra™ Etch chamber available from Applied Materials of Santa Clara, Calif.

A system controller 190 is coupled to the processing system 100 for controlling the processing system 100 or components thereof. For example, the system controller 190 may control the operation of the processing system 100 using a direct control of the chambers 104, 106, 108, 116, 118, 110, 120, 122, 124, 126, 128, 130 of the processing system 100 or by controlling controllers associated with the chambers 104, 106, 108, 116, 118, 110, 120, 122, 124, 126, 128, 130. In operation, the system controller 190 enables data collection and feedback from the respective chambers to coordinate performance of the processing system 100.

The system controller 190 generally includes a central processing unit (CPU) 192, memory 194, and support circuits 196. The CPU 192 may be one of any form of a general purpose processor that can be used in an industrial setting. The memory 194, or non-transitory computer-readable medium, is accessible by the CPU 192 and may be one or more of memory such as random access memory (RAM), read only memory (ROM), floppy disk, hard disk, or any other form of digital storage, local or remote. The support circuits 196 are coupled to the CPU 192 and may comprise cache, clock circuits, input/output subsystems, power supplies, and the like. The various methods disclosed herein may generally be implemented under the control of the CPU 192 by the CPU 192 executing computer instruction code stored in the memory 194 (or in memory of a particular process chamber) as, for example, a software routine. When the computer instruction code is executed by the CPU 192, the CPU 192 controls the chambers to perform processes in accordance with the various methods.

Other processing systems can be in other configurations. For example, more or fewer processing chambers may be coupled to a transfer apparatus. In the illustrated example, the transfer apparatus includes the transfer chambers 108, 110 and the holding chambers 116, 118. In other examples, more or fewer transfer chambers (e.g., one transfer chamber) and/or more or fewer holding chambers (e.g., no holding chambers) may be implemented as a transfer apparatus in a processing system.

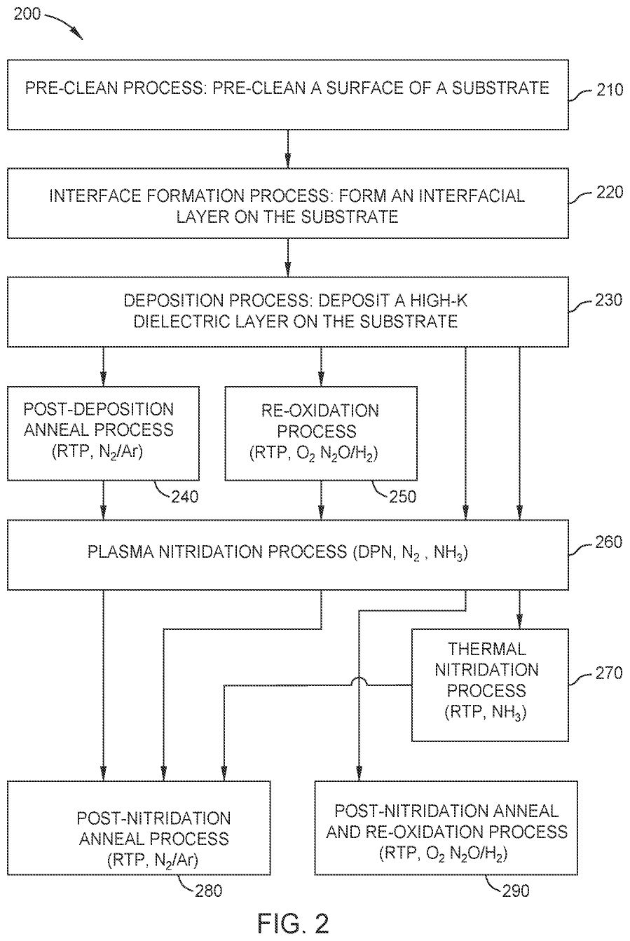

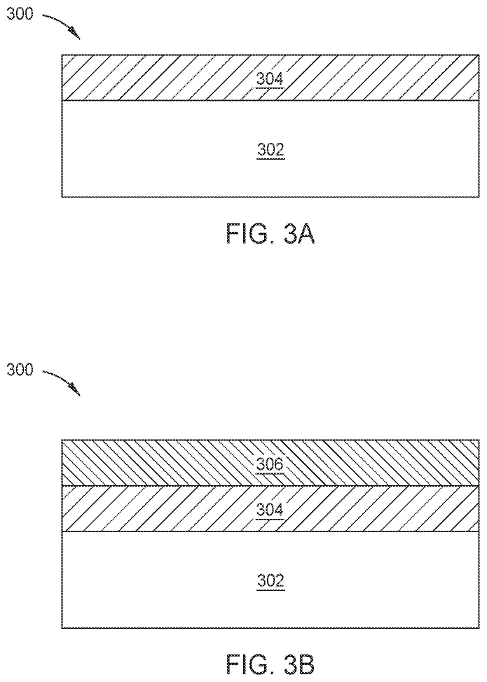

FIG. 2 is a process flow diagram of a method 200 of forming a semiconductor structure 300 according to one or more implementations of the present disclosure. FIGS. 3A and 3B are cross-sectional views of a portion of the semiconductor structure 300 corresponding to various states of the method 200. It should be understood that FIGS. 3A and 3B illustrate only partial schematic views of the semiconductor structure 300, and the semiconductor structure 300 may contain any number of transistor sections and additional materials having aspects as illustrated in the figures. It should also be noted although the method steps illustrated in FIG. 2 are described sequentially, other process sequences that include one or more method steps that have been omitted and/or added, and/or has been rearranged in another desirable order, fall within the scope of the embodiments of the disclosure provided herein.

The method 200 begins with a pre-clean process in block 210 to pre-clean a surface of the substrate 302. The pre-clean process may include etching the surface of the substrate 302 by a wet etch process using an etch solution, such as a Standard Clean 1 (SC1) etch solution including NH₄OH (ammonium hydroxide), H₂O₂ (hydrogen peroxide), and H₂O (water), or a dry etch process, for example, a SiConi™ remote plasma assisted dry etch process, in which the surface of the substrate 302 is exposed to N₂, NF₃, and NH3 plasma by-products. The pre-clean process may be performed in a pre-clean chamber, such as the processing chamber 122 or 120 shown in FIG. 1.

In block 220, an interface formation process is performed to form an interfacial layer 304 on the pre-cleaned surface of the substrate 302, as shown in FIG. 3A. The interface formation process may include a suitable thermal oxidation process, such as an enhanced in-situ steam generation (eISSG) process utilizing nitrous oxide (N₂O) gas. The interfacial layer 304 formed in block 220 is a thin amorphous silicon oxide (SiO₂) layer, having a thickness of between about 3 Å and about 10 Å, for example, about 5 Å, corresponding to one or more monolayers of silicon oxide. In some embodiments, the interfacial layer 304 may be formed by an in-situ steam generation (ISSG) process utilizing H₂ and O₂ gases, or a rapid thermal oxidation (RTO) process utilizing NH₃ and O₂ gases. The interfacial layer 304 may act as a nucleation layer of a high-κ dielectric material layer to be deposited thereon and improve quality (e.g., such as interface state density, accumulation capacitance, frequency dispersion, and leakage current) of the interface between the substrate 302 and the high-κ dielectric material layer. The interface formation process may be performed in a processing chamber, such as the processing chamber 120, 122, 124, 126, 128, or 130 shown in FIG. 1.

In some embodiments, the interface formation process in block 220 is omitted and the interfacial layer 304 is not formed prior to deposition of a high-κ dielectric material layer on the substrate 302. In that case, the interfacial layer 304 is formed by a thermal oxidation process in block 250 or block 290, described below, that thermally oxidizes the substrate 302 through a high-κ dielectric material layer deposited on the substrate 302. The interfacial layer 304 formed by the thermal oxidation process in block 250 or block 290 may be thick enough to ensure reliable device characteristics (e.g., such as interface state density, accumulation capacitance, frequency dispersion, and leakage current) and reduce atomic diffusion from the high-κ dielectric material layer to the substrate 302, having a thickness of between about 0.3 nm and about 1 nm, for example, about 0.5 nm.

In block 230, a deposition process is performed to deposit a high-κ dielectric layer 306 on the exposed surface of the semiconductor structure 300 (i.e., the interfacial layer 304, as shown in FIG. 3B, if the interfacial layer 304 is formed in block 220, and the substrate 302 if the interfacial layer 304 is not formed in block 220). The high-κ dielectric layer 306 may be formed of high-κ dielectric material, such as hafnium dioxide (HfO₂), zirconium dioxide (ZrO₂), ytterbium oxide (Y₂O₃), or aluminum oxide (Al₂O₃). The deposition process may include an atomic layer deposition (ALD) process, in which a metal-containing precursor and an oxygen-containing precursor are alternately delivered to the exposed surface of the semiconductor structure 300. In some embodiments, the metal-containing precursor is purged prior to delivering the oxygen-containing precursor. The metal may be a transition metal, such as hafnium (Hf), zirconium (Zr), or titanium (Ti), a rare-earth metal, such as lanthanum (La), ytterbium (Yb), or yttrium (Y), an alkaline earth metal, such as strontium (Sr), or other metal such as aluminum (Al). For the oxidant, any oxygen-containing precursor may be used that may react with the metal. For example, the oxygen-containing precursor may be or include water, diatomic oxygen, ozone, a hydroxyl-containing precursor or alcohol, nitrogen-and-oxygen-containing precursors, plasma-enhanced oxygen including locally or remotely enhanced oxygen, or any other material including oxygen that may be incorporated with the metal to produce a layer of an oxide of the metal over the substrate 302. In one example, the metal-containing precursor is hafnium tetrachloride (HfCl₄) and the oxidant is water (H₂O) to form a hafnium dioxide (HfO₂) layer. The ALD process may be performed at a temperature of between about 200° C. and about 400° C., for example, about 270° C. The high-κ dielectric layer 306, as deposited by the ALD process, may be amorphous and have a thickness of between about 10 Å and about 30 Å. The deposition process may be performed in a processing chamber, such as the processing chamber 120, 122, 124, 126, 128, or 130 shown in FIG. 1.

In block 240, an optional post-deposition anneal process is performed to harden and densify the as-deposited high-κ dielectric layer 306. Crystallization of the as-deposited amorphous high-κ dielectric layer 306 may occur. The post-deposition anneal process may include a thermal anneal process in an inert ambient, such as in a nitrogen (N₂) and argon (Ar) ambient, performed in a rapid thermal processing (RTP) chamber, such as RADOX™ chamber, available from Applied Materials, Inc., located in Santa Clara, Calif. The RTP chamber may be any of the processing chambers 120, 122, 124, 126, 128, and 130 shown in FIG. 1. The post deposition anneal process may thermally harden and densify the interfacial layer 304 and the high-κ dielectric layer 306.

The post deposition anneal process may be performed for between about 1 second and about 60 seconds, at a temperature of between about 500° C. and about 800° C., and at a pressure of between about 0.01 Torr and 10 Torr.

In block 250, alternative to the post-deposition anneal process in block 240, an optional re-oxidation process is performed to thermally oxidize the substrate 302. The re-oxidation process may include a thermal anneal process in an oxygen (O₂), nitrous oxide (N₂O), and H₂ ambient, performed in a rapid thermal processing (RTP) chamber, such as RADOX™ chamber, available from Applied Materials, Inc., located in Santa Clara, Calif. The RTP chamber may be any of the processing chambers 120, 122, 124, 126, 128, and 130 shown in FIG. 1. The re-oxidation process in block 250 may thermally oxidize the underlying layer through the high-κ dielectric layer 306, and thus thicken the interfacial layer 304, if the interfacial layer 304 is formed in block 220, to a thickness of between about 3 Å and about 10 Å, and form an interfacial layer 304 in the substrate 302 near the interface with the high-κ dielectric layer 306, if an interfacial layer 304 is not formed in block 220.

The re-oxidation process may be performed for between about 1 second and about 30 seconds, at a temperature of between about 400° C. and about 900° C., and at a pressure of between about 0.01 Torr and 100 Torr.

In block 260, a plasma nitridation process is performed to insert nitrogen atoms into vacancies and defects in the high-κ dielectric layer 306. The plasma nitridation process may be a decoupled plasma nitridation (DPN) process performed in a DPN chamber such as CENTURA® DPN chamber, available from Applied Materials, Inc., located in Santa Clara, Calif. The DPN chamber may be any of the processing chambers 120, 122, 124, 126, 128, and 130 shown in FIG. 1. The plasma nitridation process exposes the high-κ dielectric layer 306 to nitrogen plasma, which may allow nitrogen radicals or nitrogen atoms to be incorporated within the high-κ dielectric layer 306, throughout the thickness of the high-κ dielectric layer 306. During the plasma nitridation process, nitrogen atoms may form metastable bonds with oxygen (O). Gases that may be used in the plasma process include nitrogen containing gas, such as nitrogen (N₂), ammonia (NH₃), or mixtures thereof. In one example, the nitrogen gas is ammonia (NH₃) mixed with about 3% to about 8% of nitrogen (N₂). The plasma nitridation process may not change a thickness of the high-κ dielectric layer 306 as a result of the nitrogen incorporation to vacancies and defects in the as-deposited high-κ dielectric layer 306.

The nitridation process may be performed for between about 10 seconds and about 300 seconds, at a temperature of between about 0° C. and about 500° C.

In block 270, an optional thermal nitridation process is performed to further insert nitrogen atoms into vacancies and defects in the plasma nitridated high-κ dielectric layer 306. The thermal nitridation process may include a thermal anneal process in an ammonia (NH₃) ambient, performed in a rapid thermal processing (RTP) chamber, such as RADOX™ chamber, available from Applied Materials, Inc., located in Santa Clara, Calif. The RTP chamber may be any of the processing chambers 120, 122, 124, 126, 128, and 130 shown in FIG. 1.

The thermal nitridation process may be performed for between about 10 seconds and about 300 seconds, at a temperature of between about 700° C. and about 900° C., and at a pressure of between about 10 Torr and 740 Torr.

In block 280, a post-nitridation anneal process is performed to passivate the remaining chemical bonds in the plasma nitridated high-κ dielectric layer 306. The post-nitridation anneal process may include a spike thermal anneal process in a nitrogen (N₂) and argon (Ar) ambient, performed in a rapid thermal processing (RTP) chamber, such as RADOX™ chamber, available from Applied Materials, Inc., located in Santa Clara, Calif. The RTP chamber may be any of the processing chambers 120, 122, 124, 126, 128, and 130 shown in FIG. 1. The post-nitridation anneal process may passivate metastable nitrogen bonds formed in the plasma nitridation process in block 240 and crystallization of the amorphous high-κ dielectric layer 306 may occur.

The spike thermal anneal process may be performed for between about 1 second and about 30 seconds, at a temperature of between about 700° C. and about 850° C., and at a pressure of between about 10 Torr and 740 Torr.

In block 290, alternative to the post-nitridation anneal process in block 280, a post-nitridation anneal and re-oxidation process is performed to simultaneously passivate the remaining chemical bonds in the high-κ dielectric layer 306, as in block 280, and thermally oxidize the substrate 302, as in block 250. The post-nitridation anneal and re-oxidation process in block 290 is the same as the re-oxidation process in block 250. Thus, the details of the post-nitridation anneal and re-oxidation process in block 290 are omitted here.

In the embodiments described herein, the systems and the methods of forming high-quality thin high-κ dielectric material layers are provided. The properties of such high-κ dielectric material layers may be well controlled. For example, the nitridation processes in blocks 260 and 270 may be controlled to provide a nitrogen incorporation in the high-κ dielectric layer 306 of between about 3 atomic % and about 20 atomic %, to achieve a higher κ-value than a higher nitrogen incorporation, and better structural stabilization than a lower nitrogen incorporation. The anneal processes in blocks 240, 270, 280, and 290 may also be controlled to provide grains in the high-κ dielectric layer 306 having a size larger than about 20 Å, to reduce leakage currents through the high-κ dielectric layer 306.

While the foregoing is directed to embodiments of the present disclosure, other and further embodiments of the disclosure may be devised without departing from the basic scope thereof, and the scope thereof is determined by the claims that follow.

1. A method of forming a semiconductor structure, the method comprising:
forming a semiconductor structure, comprising:
pre-cleaning a surface of a substrate;
forming an interfacial layer on the pre-cleaned surface of the substrate;
depositing a high-κ dielectric layer on the interfacial layer;
performing a plasma nitridation process to insert nitrogen atoms in the deposited high-κ dielectric layer; and
performing a post-nitridation anneal process to passivate chemical bonds in the plasma nitridated high-κ dielectric layer.

2. The method of claim 1, wherein the forming of the semiconductor structure is performed in a processing system without breaking vacuum.

3. The method of claim 1, wherein
the interfacial layer comprises silicon oxide (SiO₂), and
the forming of the interfacial layer comprises thermally oxidizing the substrate utilizing nitrous oxide (N₂O) gas.

4. The method of claim 1, wherein the high-κ dielectric layer comprises hafnium oxide (HfO₂).

5. The method of claim 1, wherein the plasma nitridation process comprises exposing the deposited high-κ dielectric layer to nitrogen plasma using a mixture of nitrogen (N₂) and ammonia (NH₃) gas.

6. The method of claim 1, wherein the post-nitridation anneal process comprises spike annealing the deposited high-κ dielectric layer in a nitrogen (N₂) and argon (Ar) ambient at a temperature of between of between 700° C. and 850° C.

7. The method of claim 1, further comprising:
performing a post-deposition anneal process, prior to the plasma nitridation process, to harden and densify the deposited high-κ dielectric layer.

8. The method of claim 7, wherein the post-deposition anneal process comprises annealing the deposited high-κ dielectric layer in a nitrogen (N₂) and argon (Ar) ambient at a temperature of between 500° C. and 800° C.

9. The method of claim 1, further comprising:
performing a thermal nitridation process, prior to the post-nitridation anneal process, to further insert nitrogen atoms in the plasma nitridated high-κ dielectric layer.

10. The method of claim 9, wherein the thermal nitridation process comprises annealing the plasma nitridated high-κ dielectric layer in an ammonia (NH₃) ambient at a temperature of between 700° C. and 900° C.

11. A method of forming a semiconductor structure, the method comprising:
forming a semiconductor structure, comprising:
pre-cleaning a surface of a substrate;
depositing a high-κ dielectric layer on the substrate; and
performing a plasma nitridation process to insert nitrogen atoms in the deposited high-κ dielectric layer.

12. The method of claim 1, wherein the forming of the semiconductor structure is performed in a processing system without breaking vacuum.

13. The method of claim 11, further comprising:
forming an interfacial layer on the pre-cleaned surface of the substrate, comprising thermally oxidizing the substrate utilizing nitrous oxide (N₂O) gas, wherein the interfacial layer comprises silicon oxide (SiO₂).

14. The method of claim 11, wherein the high-κ dielectric layer comprises hafnium oxide (HfO₂).

15. The method of claim 11, wherein the plasma nitridation process comprises exposing the deposited high-κ dielectric layer to nitrogen plasma using a mixture of nitrogen (N₂) and ammonia (NH₃) gas.

16. The method of claim 11, further comprising:
performing a re-oxidation process, prior to the plasma nitridation process, to thermally oxidize the substrate; and
performing a post-nitridation anneal process, subsequent to the plasma nitridation process, to passivate chemical bonds in the plasma nitridated high-κ dielectric layer.

17. The method of claim 16, wherein
the re-oxidation process comprises annealing the high-κ dielectric layer in an oxygen (O₂), nitrous oxide (N₂O), and H₂ ambient at a temperature of between 400° C. and 900° C.; and
the post-nitridation anneal process comprises spike annealing the plasma nitridated high-κ dielectric layer in a nitrogen (N₂) and argon (Ar) ambient at a temperature of between of between 700° C. and 850° C.

18. The method of claim 11, further comprising:
performing a re-oxidation process, subsequent to the plasma nitridation process, to passivate the remaining chemical bonds in the plasma nitridated high-κ dielectric layer and thermally oxidize the substrate.

19. The method of claim 18, wherein the re-oxidation process comprises annealing the high-κ dielectric layer in an oxygen (O₂), nitrous oxide (N₂O), and H₂ ambient at a temperature of between 400° C. and 900° C.

20. A processing system, comprising:
a first processing chamber;
a second processing chamber;
a third processing chamber;
a fourth processing chamber;
a fifth processing chamber; and
a system controller configured to:
pre-clean a surface of a substrate in the first processing chamber;
form an interfacial layer on the pre-cleaned surface of the substrate in the second processing chamber;
deposit a high-κ dielectric layer on the interfacial layer in the third processing chamber;
expose the deposited high-κ dielectric layer to nitrogen plasma in the fourth processing chamber; and
anneal the plasma nitridated high-κ dielectric layer in the fifth processing chamber,
wherein the substrate is transferred among the first, second, third, fourth, and fifth processing chambers without breaking vacuum environment in the processing system.
